(19) United States
(12) Patent Application Publication
(10) Pub. No.: US 2024/0136149 A1
(43) Pub. Date: Apr. 25, 2024

(54) ELECTRONIC TWEEZERS

(71) Applicant: ZHEJIANG UNIVERSITY, Hangzhou (CN)

(72) Inventors: He TIAN, Hangzhou (CN); Tulai SUN, Hangzhou (CN); Tianxing REN, Hangzhou (CN); Wanru ZHANG, Hangzhou (CN); Xinkai CHEN, Hangzhou (CN); Ze ZHANG, Hangzhou (CN)

(21) Appl. No.: 18/548,062

(22) PCT Filed: Feb. 28, 2021
(86) PCT No.: PCT/CN2021/078354

§ 371 Date: Aug. 24, 2023

(51) Int. Cl. H01J 37/30

(52) U.S. Cl. CPC H01J 37/3005

(57) ABSTRACT

The present invention relates to a method for manipulating a tiny object, including: providing a charged particle beam; forming a non-uniform charge distribution in a fluid medium; and applying, to a tiny object, a gradient force formed by the non-uniform charge distribution. The present invention extends manipulation to a nanoscale, and can be applied to various microscopic tiny objects such as conductors, non-conductors, and living or non-living biological cells or organelles, and therefore surely promote great progress in the fields of physics, chemistry, biology and medicine.

### TECHNICAL FIELD

The present invention relates to the field of physics, and in particular to electronic tweezers.

### BACKGROUND ART

The manipulation for microscopic objects is always the dream of human beings. Numerous science fiction books and movies present many imaginary perfect pictures for people, for example, manufacturing portable devices by means of micro-machinery, using nano-robots to treat diseases, and the like. Such scenarios are also gradually becoming a reality. In 1970, Ashikin observed that micron-sized particles can be captured with optical forces. After that, optical tweezers were invented and developed into powerful tools in many research fields. Thus, “optical tweezers” also won the 2018 Nobel Prize in Physics. Other methods are also developed for manipulation of microscopic objects. For example, an atomic force microscope (AFM) may manipulate a single atom. Acoustic tweezers utilizing acoustic surface waves may capture particles greater than a few hundred nanometers.

The quantum effect and the surface/interface effect of nanomaterials cause a series of revolutions in the fields of physics, chemistry, biology, etc. However, accurate manipulation of nanoscale objects lacks an effective method. People have been expecting that a new manipulation technology can solve this problem.

### SUMMARY

Regarding the technical problems in the prior art, the present invention provides a method for manipulating a tiny object, including: providing a charged particle beam; forming a non-uniform charge distribution in a fluid medium; and applying, to a tiny object, a gradient force formed by the non-uniform charge distribution.

According to the method, the gradient force is a Coulomb force.

According to the method, the charged particle beam causes the tiny object to be charged.

According to the method, the tiny object is at least partially a conductor.

According to the method, the tiny object is at least partially a non-conductor.

According to the method, the charged particle beam is an electron beam.

According to the method, the charged particle beam is a vortex beam.

According to the method, the non-uniform charge distribution is generated by the charged particle beam passing through a region of the fluid medium.

According to the method, the non-uniform charge distribution is defined by a shape of a charged particle beam probe.

According to the method, the non-uniform charge distribution is generated by the charged particle beam scanning a region of the fluid medium.

According to the method, the non-uniform charge distribution is defined by a shape of a charged particle beam probe scanning region.

According to the method, a charged particle beam probe or probe scanning region surrounds or at least partially surrounds the tiny object.

According to the method, the shape of the probe or probe scanning region in a plane of the tiny object is a ring, and the tiny object is located in the ring.

According to the method, the shape of the probe or the probe scanning region in the plane of the tiny object is an arc, and the tiny object is located on one side of a circle center of the arc.

According to the method, a ratio of a size of the probe or the probe scanning region to a size of the tiny object in a plane of the tiny object is about 1.5-1:1.

According to the method, the tiny object does not exceed a range of the probe or the probe scanning region.

According to the method, the shape of the charged particle beam probe or the probe scanning region in a vertical direction includes a neck region configured to apply a gradient force in the vertical direction.

According to the method, the gradient force is used for capturing the tiny object.

The method further includes: changing the gradient force by changing a dose rate of the charged particle beam.

The method further includes: changing the gradient force by changing the shape of a charged particle beam probe or probe scanning region.

The method further includes: changing the gradient force by changing a position of a charged particle beam probe or probe scanning region relative to the tiny object.

The method further includes: moving a position of the tiny object horizontally by adjusting a horizontal position of a charged particle beam probe or probe scanning region.

The method further includes: adjusting a height of the tiny object by adjusting a vertical position of a charged particle beam probe or probe scanning region.

The method further includes: rotating the tiny object by adjusting an angle of a charged particle beam probe or probe scanning region relative to the tiny object.

The method further includes: rotating the tiny object through an angular momentum transfer of a charged particle beam probe to the tiny object.

According to another aspect of the present invention, provided are a device for manipulating a tiny object, including: a charged particle gun, configured to provide a charged particle beam; an adjustment device, configured to adjust the charged particle beam from the charged particle gun; and a fluid medium chamber, configured to accommodate a fluid medium and a tiny object; where the charged particle beam is adjusted to form a non-uniform charge distribution in the fluid medium within the fluid medium chamber, such that a gradient force is applied to the tiny object.

According to the device, the charged particle gun includes an electron gun.

According to the device, the fluid medium chamber includes a liquid cell.

According to the device, the adjustment device includes one or more electromagnetic lenses.

According to the device, the adjustment device includes one or more diaphragms.

According to the device, the adjustment device includes a vortex beam device configured to generate a charged particle beam carrying orbital angular momentum.

According to the device, the vortex beam device includes one or more of a computer-generated hologram diaphragm, an annular diaphragm, and an arc-shaped diaphragm.

According to the device, the adjustment device is configured to move the tiny object horizontally by adjusting a horizontal position of a charged particle beam probe or probe scanning region.

According to the device, the adjustment device is configured to adjust a height of the tiny object by adjusting a vertical position of a charged particle beam probe or probe scanning region.

According to the device, the adjustment device is configured to rotate the tiny object by adjusting an angle of a charged particle beam probe or probe scanning region relative to the tiny object.

According to the device, the adjustment device is configured to rotate the tiny object by adjusting an angular momentum transfer of a charged particle beam probe to the tiny object.

The present invention extends manipulation to a nanoscale, and can be applied to various microscopic tiny objects such as conductors, non-conductors, and living or non-living biological cells or organelles, and therefore surely promote great progress in the fields of physics, chemistry, biology and medicine.

### BRIEF DESCRIPTION OF THE DRAWINGS

Preferred implementations of the present invention is further descried in detail below in combination with the accompanying drawings.

FIG. 1 and FIG. 2 are schematic diagrams of a working principle of electronic tweezers according to an embodiment of the present invention.

FIG. 3 and FIG. 4 are schematic diagrams of a working principle of electronic tweezers according to another embodiment of the present application.

FIGS. 5A to 5C are embodiments of performing metal palladium (Pd) particle manipulation with an electron vortex beam according to an embodiment of the present invention.

FIGS. 6A to 6C illustrate theoretical calculation results of a potential distribution of a Pd particle at different center deviation positions in the embodiments of FIGS. 5A to 5C. FIG. 6D illustrates a density distribution and a potential distribution of an EVB. FIG. 6E illustrates a change in a Coulomb force in a horizontal direction.

FIGS. 7A to 7D illustrate electron beam probes or probe scanning regions of different shapes according to an embodiment of the present invention.

FIGS. 8A and 8B are schematic diagrams of moving a height of a tiny object according to an embodiment of the present invention.

FIG. 9 illustrates an influence of different factors on a Coulomb force according to an embodiment of the present invention.

FIG. 10A is a schematic diagram of changing an angle of a tiny object according to an embodiment of the present invention.

FIG. 10B is a schematic diagram of changing an angle of a tiny object according to another embodiment of the present invention.

FIG. 10C is a schematic diagram of rotating an angle of a tiny object according to an embodiment of the present invention.

FIG. 11 is an example of nanoparticle manipulation and assembly according to an embodiment of the present invention.

FIG. 12 is an image of a nanoparticle manipulation and assembly process of the letter “J” in the embodiment shown in FIG. 11.

FIG. 13 is a schematic structural diagram of a device for manipulating a tiny object according to an embodiment of the present invention.

FIG. 14 is a schematic diagram of manipulating a tiny object according to another embodiment of the present invention.

FIG. 15 is a schematic diagram of manipulating a tiny object according to another embodiment of the present invention.

FIG. 16 is a schematic diagram of a device for manipulating a tiny object according to an embodiment of the present invention.

FIGS. 17A to 17C are schematic diagrams of manufacturing a micro device according to an embodiment of the present invention.

FIG. 18 illustrates a flowchart of a method for manufacturing a micro device according to an embodiment of the present invention.

FIG. 19 is a schematic structural diagram of a device for manufacturing a micro device according to an embodiment of the present invention.

FIGS. 20A to 20C are schematic diagrams of a manufacturing process of a micro device according to an embodiment of the present invention.

### DETAILED DESCRIPTION

To describe the purpose, the technical solutions and the advantages of embodiments of the present invention more clearly, the technical solutions in the embodiments of the present invention are described clearly and integrally below by combining the accompanying drawings in the embodiments of the present invention. Apparently, the described embodiments are some of the embodiments of the present invention, but not all the embodiments. Based on the embodiments of the present invention, all other embodiments obtained by a person skilled in the art without involving an inventive effort shall fall within the scope of protection of the present invention.

In the following detailed description, reference may be made to the accompanying drawings, which are taken as part of the present application to illustrate specific embodiments of the present application. In the accompanying drawings, similar reference numerals describe generally similar components in different figures. Various specific embodiments of the present application are described in sufficient detail below, so that a person skilled in the art with related knowledge and technology may implement the technical solutions of the present application. It should be understood that other embodiments may be utilized or structural, logical, or electrical changes may be made to the embodiments of the present application.

The present invention provides a solution for realizing high-precision manipulation of a microscopic object by using a charged particle beam, such as an electron beam, which may realize 4D high-precision manipulation of nanoscale three-dimensional rotation, and may also realize high-precision manipulation of a higher scale (such as a micron scale or above), and will become a basic tool in the fields of physics, chemistry, biology and the like, thereby bringing revolutionary progress in the whole science and technology field.

As defined herein, “charged particles” include electrons, protons, and other charged particles, such as α particles, Ga⁺ or Xe⁺. Although in the following description, an example of taking electrons as charged particles is described in most cases, as will be appreciated, a proton beam formed by accelerated protons may also be applied to the present invention, and may obtain a higher resolution theoretically. Of course, as the mass of charged particles increases, acceleration of these particles also requires higher energy. Therefore, the charged particles of the present invention are not limited to electrons, and other charged particles, such as protons, α particles (He⁺), Ga⁺ or Xe⁺ may also be applied to the present invention.

As defined herein, a “charged particle beam” refers to a beam stream formed by acceleration of charged particles. The energy of a single charged particle in the charged particle beam may characterize the degree of acceleration of the charged particle. A dose rate of the charged particle beam represents the number of charges per unit area per unit time, and may reflect the density of charged particles in the charged particle beam.

As defined herein, an “electron beam” refers to a beam stream formed by acceleration of electrons, and has been widely used in many fields such as transmission electron microscopes and scanning electron microscopes, electron beam lithography, electron beam exposure, and electron beam welding.

As defined herein, a “probe” refers to a portion of the charged particle beam approaching a target region. In some embodiments, a focusing position and a beam configuration of the charged particle beam may be adjusted by means of an adjustment device such as an electromagnetic lens and a diaphragm, so as to control a shape of the probe. In some embodiments, a scanning region of the charged particle beam, i.e., the scanning region of the probe, may be controlled by an adjustment device such as a scanning coil.

As defined herein, a “tiny object” refers to an object having sizes of three dimensions in sub-angstroms, 1/10 nanometers, ¼ nanometers, ½ nanometers or 1 nanoscale, several nanoscales, tens of nanoscales, hundreds of nanoscales, and a micrometer scale or above; or, an object having sizes of two dimensions in sub-angstroms, 1/10 nanometers, ¼ nanometers, ½ nanometers or 1 nanoscale, several nanoscales, tens of nanoscales, hundreds of nanoscales, and a micrometer scale or above; or, an object having a size of one dimension in sub-angstroms, 1/10 nanometers, ¼ nanometers, ½ nanometers or 1 nanoscale, several nanoscales, tens of nanoscales, hundreds of nanoscales, and a micrometer scale or above.

As defined herein, a “fluid medium” refers to a substance having fluidity, and includes a liquid, a colloid, a gas, etc. When the charged particle beam passes through the fluid medium, some of the charged particles interact with the fluid medium. On the one hand, the fluidity of the fluid medium may reduce the resistance of manipulating a tiny object, and on the other hand, the density of the fluid medium also causes a sufficient number of fluid media that interact with the charged particles to generate a force required for operating a tiny object. In some embodiments, the fluid medium may be water or an aqueous solution of other substances. In some embodiments, the fluid medium may also be an organic solvent or a solution formed by dissolving other substances in an organic solvent. In some embodiments, the fluid medium may also be a suspension, an emulsion, or a colloid.

As defined herein, “charge distribution” refers to a spatial spreading position of positive and negative charges. Since the process in which the charged particle beam passes through the fluid medium and interacts with the fluid medium is a continuous process, the charge distribution in the fluid medium and on the manipulated tiny object is an apparent result formed by dynamic balance of charges. A configuration of the charged particle beam and a position of the charged particle beam in the fluid medium may be designed and controlled with high precision to form a charge distribution in a designated region.

As defined herein, a “gradient force” refers to a force effect that is generated for a charged tiny object due to a non-uniform charge distribution. Different charge distributions and electrical properties may produce different gradient forces. For example, the charge distribution formed by a charged particle beam in a surrounding region of a charged tiny object may generate a pulling force or a pushing force. An annular or substantially annular charge distribution may form a “force well” of the gradient force. When the charged tiny object is located in the “force well”, the charged tiny object may be constrained in the “force well” and “captured”.

As defined herein, “manipulation” refers to changing a relative position and a relative angle of an object, and any one of the two. Two objects respectively have respective directions. If a relative angle between the respective directions of the two changes, the relative angle may be considered to change. In other words, even if the relative position is unchanged, the relative angle may also change.

The technical solutions of the present invention are described in detail by taking “electronic tweezers” as an example.

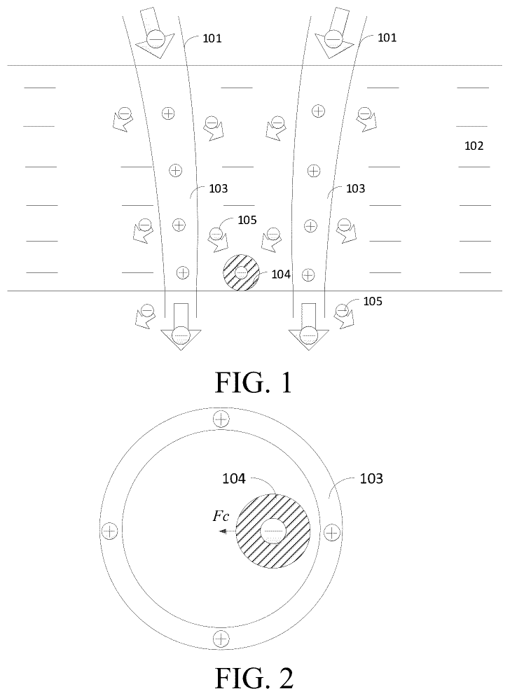

FIG. 1 and FIG. 2 are schematic diagrams of a working principle of electronic tweezers according to an embodiment of the present invention. FIG. 1 is a cross-sectional view parallel to a surface of a fluid medium layer. FIG. 2 is a top view perpendicular to a surface of a fluid medium layer. In this embodiment, the tiny object is a conductor, such as a metal. As shown in the drawing, a controlled electron beam 101 passes through a fluid medium layer (i.e., a fluid medium) 102. The portion of the electron beam 101 passing through the fluid medium layer 102 is substantially an annular region 103. A tiny object 104 is located in the annular region 103 of the electron beam 101 in the fluid medium layer. When the electron beam 101 passes through the fluid medium layer 102, some of incident electrons interact with the fluid medium to excite secondary electrons 105. Most of the incident electrons do not stay in the fluid medium layer 102 even after a non-elastic collision, but still continue to penetrate out of the fluid medium layer 102. Therefore, the region 103 through which the electron beam passes in the fluid medium layer 102 becomes a positively charged region due to the loss of electrons.

On the other hand, since the tiny object 104 itself is a conductor, the excited secondary electrons 105 may enter the tiny object 104. The secondary electrons 105 may further undergo non-elastic scattering in the tiny object 104 to produce low-energy and cascaded secondary electrons, while the energy per se will be further reduced. Due to the limitation of the work function of the conductor, some of the low-energy secondary electrons and the cascaded secondary electrons are not separated from the tiny object 104. Therefore, the tiny object 104 is negatively charged due to increasing electrons. Thus, the negatively charged tiny object 104 is surrounded by the positively charged annular region 103 and is constrained therein. As shown in FIG. 2, a resultant force Fc of a Coulomb force between the tiny object 104 and the annular region 103 points to the center of the annular region 103. If a position of the negatively charged tiny object 104 deviates from the center of the annular region 103, the Coulomb force Fc will push the tiny object 104 back to the center of the annular region 103. The non-uniform charge distribution (i.e., the positively charged annular region 103) in the fluid medium layer 102 forms a gradient force, i.e., a Coulomb force, thereby providing a basis for manipulation of the tiny object.

In this way, when the electron beam 101 is controlled to change the position, the central position of the annular region 103 also changes, and the Coulomb force Fc enables the tiny object 104 also to change the position and move to a new central position of the annular region 103. It seems that the tiny object 104 is clamped by intangible “tweezers” to move from an original position to a new position.

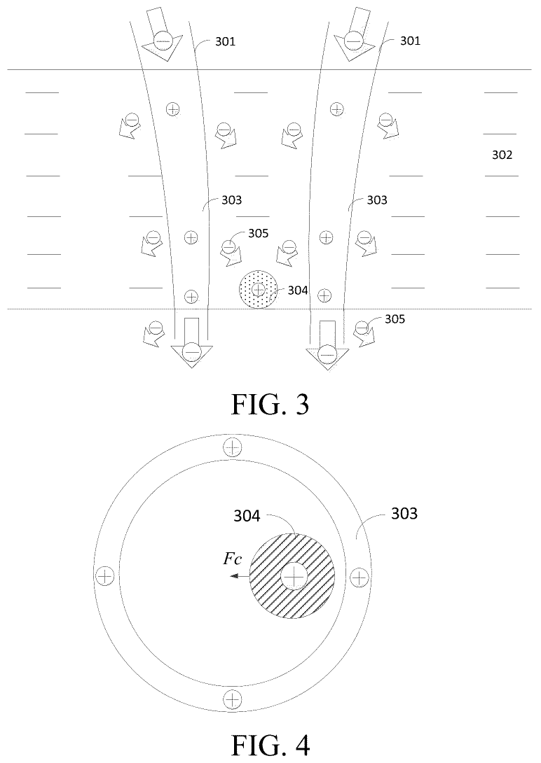

FIG. 3 and FIG. 4 are schematic diagrams of a working principle of electronic tweezers according to another embodiment of the present invention. FIG. 3 is a cross-sectional view parallel to a surface of a fluid medium layer. FIG. 4 is a top view perpendicular to a surface of a fluid medium layer. In this embodiment, the tiny object is a non-conductor, such as an insulator. The interaction between an electron beam 301 and a fluid medium layer 302 is the same as that of the embodiment shown in FIG. 1 and FIG. 2, and details are not described herein again. Excited secondary electrons 305 may enter a tiny object 304 to generate cascaded secondary electrons, and some of the cascaded secondary electrons are separated from the tiny object 304 so that the tiny object 304 is positively charged. The positively charged tiny object 304 is surrounded by a positively charged annular region 303 and is constrained therein. As shown in FIG. 4, a resultant force Fc of a Coulomb force between the tiny object 304 and the annular region 303 also points to the center of the annular region 303. In this way, when the central position of the annular region 303 also changes, the Coulomb force Fc enables the tiny object 304 also to change the position and move to a new central position of the annular region 303. It seems that the tiny object 304 is clamped by intangible “tweezers” to move from an original position to a new position.

For ease of understanding, the possible principles of the present invention are described without limitation above, and the actual process may be more complex. Therefore, the present invention is not limited to the foregoing description, and is not limited to the physical theory in the foregoing description, either.

In some embodiments, the electron beam is a planar wave or a spherical wave. A configuration of the electron beam may be adjusted by an adjustment device such as a diaphragm, thereby defining a shape of an electron beam probe. When the electron beam is transmitted through a fluid medium, a non-uniform charge distribution is formed in the fluid medium. The shape of the electron beam probe defines a region of the non-uniform charge distribution.

In some embodiments, the electron beam is a vortex wave, i.e., an electron vortex beam (EVB). The vortex wave is also referred to as a wave with a topological charge or a wave with a phase singular point. The vortex wave was initially found in radio waves and carries orbital angular momentum (OAM), and the topological charge m is a non-zero integer, for example, +1 or −1. The electron wave has a very short wavelength (on the order of picometer), and is suitable for creating an atomic-scale vortex wave. At present, the application of the EVB has been relatively mature in related technologies such as electron microscopes and electron energy loss spectroscopy (EELS). When the EVB is transmitted through a fluid medium, an annular or substantially annular non-uniform charge distribution is formed in the fluid medium. Such a probe shape may be conveniently used to capture a tiny object. There are various methods for generating the EVB in the prior art, which fall with within the scope of the present invention.

In some embodiments, a non-uniform charge distribution is generated by rapidly scanning a region of the fluid medium with an electron beam. Because the electron beam scanning speed is much higher than the change speed of the charge distribution in the fluid medium, the non-uniform charge distribution formed by scanning the region in the fluid medium and the non-uniform charge distribution formed by an electron beam probe passing through the same region in the fluid medium have no essential difference. The shape of the electron beam probe scanning region defines a region of the non-uniform charge distribution.

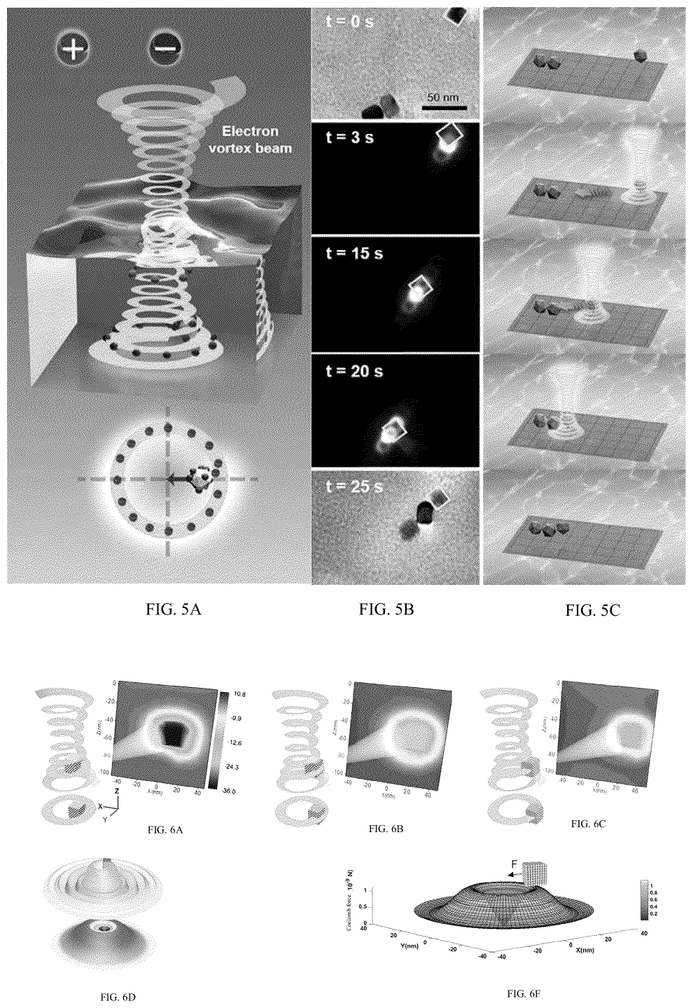

FIGS. 5A to 5C are embodiments of performing metal palladium (Pd) particle manipulation with an electron vortex beam according to an embodiment of the present invention. In this embodiment, a water layer including a plurality of nanoscale Pd particles is enclosed in a K-kit liquid cell and placed in a transmission electron microscope (TEM). A high-energy electron beam of about 200 keV is generated by an electron gun, and then the EVB is generated by a computer-generated hologram diaphragm. An annular non-uniform charge distribution is formed in the water layer by using the EVB to realize manipulation of the nanoscale Pd particles.

FIG. 5A illustrates a schematic diagram of an EVB forming a positively charged annular region in a water layer. Similar to the case of FIG. 2, a Pd particle to be moved is enclosed in an annular region formed by the EVB. FIG. 5B illustrates electron microscope images of a whole process of using an EVB to move a Pd particle. The size of the moved Pd particle is about 20 nm. At a time t=0 s, the Pd particle to be moved is located in the upper right, and the two particles in the lower left are taken as a moving target position and reference. As shown in the drawing, from t=0 s to t=25 s, the Pd particle in the upper right moves from a position away from the two particles in the lower left to a position close to the two particles in the lower left. For ease of understanding, FIG. 5C illustrates a schematic diagram of a whole process of moving a Pd particle by an EVB at different times.

According to the electromagnetic theory, the presence of free charges may produce polarization. The distribution of all charges satisfies a Poisson equation:

$${∇}^{2} ϕ ( r ) = - \frac{1}{{ε}_{0}} ( {ρ}_{f} + {ρ}_{p - f} + {ρ}_{p} ) ,$$

where ρ_{f} represents the charge density of free charges; ρ_{p-f} represents the charge density of polarized charges near the free charges; ρₚ represents the charge density of the polarized charges on an interface; and ε₀ represents a dielectric constant in a vacuum. After merging of the first two items, the foregoing equation is:

$${∇}^{2} ϕ ( r ) = - ( \frac{1}{ε} {ρ}_{f} + \frac{1}{{ε}_{0}} {ρ}_{p} ) ,$$

where ε represents a dielectric constant of a medium.

Assuming that the Pd particle to be moved is spherical, the potential of the free charges is:

$${ϕ}_{f} ( r ) = \int \frac{{ρ}_{f} ( {r}^{′} )}{4 πε ( {r}^{′} ) \vert r - {r}^{′} \vert} {dr}^{′} .$$

Next, polarized charges at the interface are obtained by an electric field:

E(r)=−∇ϕ(r)≈−∇ϕ_{f}(r).
where E represents a metal surface polarization electric field. The density of the polarized charges may be given by the following equation:

ρₚ=−eₙ·(P₂−P₁); and

P=(ε−ε₀)E,
where eₙ represents a unit normal vector of a sample pointing to a fluid medium at the interface, P₂ represents the polarization intensity of one side of the sample near the interface, and P₁ represents the polarization intensity of one side of the fluid medium near the interface.

According to the Gaussian theorem, the polarized charges around the free charges are:

Q_{p-f}=−(1−ε₀/ε)∫ρ_{f}(r)dr

Thus, the polarization potential generated due to polarization is:

$${ϕ}_{p} ( r ) = - {Q}_{p - f} \int \frac{{ρ}_{p} ( {r}^{′} )}{4 {πε}_{0} \vert r - {r}^{′} \vert \int {ρ}_{p} ( {r}^{″} ) {dr}^{″}} {dr}^{′} ,$$

where ρ represents the distribution of polarized charges at the interface. Finally, the distribution of all charges satisfies the following formula:

$$ϕ ( r ) = {ϕ}_{f} ( r ) + {ϕ}_{p} ( r ) = \int \frac{{ρ}_{f} ( {r}^{′} )}{4 πε ( {r}^{′} ) \vert r - {r}^{′} \vert} dr - {Q}_{p - f} \int \frac{{ρ}_{p} ( {r}^{′} )}{4 {πε}_{0} \vert r - {r}^{′} \vert \int {ρ}_{p} ( {r}^{″} ) {dr}^{″}} {dr}^{′} .$$

FIGS. 6A to 6C illustrate theoretical calculation results of a potential distribution of a Pd particle at different center deviation positions. As the deviation distance increases, the potential of the Pd particle changes significantly due to the reduction of electrons deposited in the Pd particle. In FIG. 6A, when the Pd particle deviates from the center by 10 nm, the non-uniformity of the potential distribution is the highest, and the Coulomb force is at a higher level; in FIG. 6B, when the Pd particle deviates from the center by 20 nm, the Pd particle is close to a charge region formed by an EVB, the non-uniformity of the potential distribution is significantly reduced, and the Coulomb force is greatly reduced; and in FIG. 6C, when the Pd particle deviates from the center by 30 nm, the Pd particle enters the charge region formed by the EVB, the non-uniformity of the potential distribution is very low, and the Coulomb force is at the lowest level. Since the Coulomb force is a basis for manipulating a tiny object, it can be easily seen from FIGS. 6A to 6C that a preferred manipulation range is an annular region formed by the EVB in water. If this range is exceeded, the force used to manipulate the tiny object will decrease substantially.

FIG. 6D illustrates a density distribution and a potential distribution of an EVB, and the density distribution is located in the upper position and the potential distribution is located in the lower position. FIG. 6E illustrates a change in a Coulomb force in a horizontal direction, and the Coulomb force reaches the extreme value at a position approximately 10 nm from the center and then gradually decreases. The direction of the Coulomb force always points to the center. FIG. 6D and FIG. 6E illustrate a relationship between a gradient force formed by non-uniformity of charge distribution and the charge distribution, and a “force well” formed by the gradient force. A tiny object to be moved is constrained in the “force well” and may move along with the “force well” to change the position, thereby realizing accurate manipulation of the tiny object.

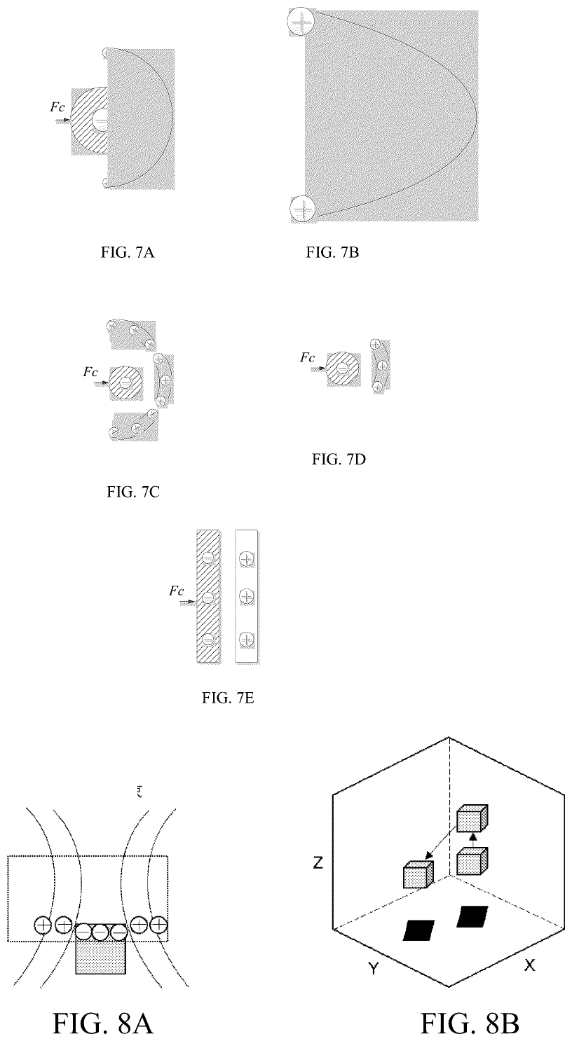

The electron beam probe or the probe scanning region may also have other shapes. FIGS. 7A to 7D illustrate electron beam probes or probe scanning regions of different shapes. As shown in the drawing, the electron beam probe or probe scanning region may be annular, arc-shaped, or the like. As will be appreciated, the shapes referred to herein include a generally or irregular certain shape.

In some embodiments, the electron beam probe or probe scanning region surrounds or at least partially surrounds the tiny object. In FIG. 7A, the electron beam probe or probe scanning region is semi-annular, and the tiny object may still be conveniently manipulated when the Coulomb force is an attractive force. In FIG. 7B, the electron beam probe or probe scanning region is a deep arc, and the tiny object is accommodated in the arc-shaped semi-closed region. Regardless of whether the Coulomb force is an attractive force or a repulsive force, the Coulomb force may well be used for manipulating the tiny object. In FIG. 7C, the electron beam probe or probe scanning region is a discontinuous semi-ring shape, and such shape does not affect manipulation. In some embodiments, the electron beam probe or probe scanning region may be merely close to the tiny object. In this way, the Coulomb force may also be applied to the tiny object. In FIG. 7D, the electron beam probe or probe scanning region is close to the tiny object to apply the Coulomb force to the tiny object. The shape of the electron beam probe or the probe scanning region corresponds to the shape of the tiny object. In FIG. 7E, the size of the tiny object extends in a length direction. The electron beam probe or probe scanning region also extends in the length direction and is close to the tiny object in a direction perpendicular to the length direction to apply a sufficient Coulomb force.

In some embodiments, the tiny object does not exceed or enter the range of the electron beam probe or probe scanning region. When the electron beam probe or probe scanning region is overlapped with the tiny object, the charge distribution will change significantly, and the gradient force used to manipulate the tiny object may be greatly reduced. Thus, in general, the tiny object does not make contact with the electron beam probe or probe scanning region. Of course, the present invention does not completely exclude such a situation.

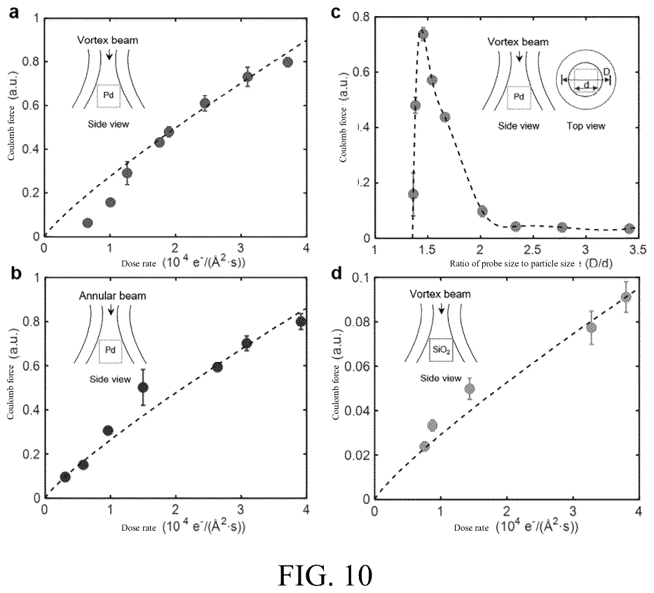

FIGS. 8A and 8B are schematic diagrams of moving a height of a tiny object according to an embodiment of the present invention. As shown in the drawing, the shape of the electron beam probe or probe scanning region in the vertical direction includes a neck region as shown by dashed lines in the drawing. As will be appreciated, in the neck region formed by cross-over of the electron beam, the electron beam has a higher dose rate. When the neck region is close enough to the tiny object, a gradient force may be applied in the vertical direction. Of course, the gradient force in the horizontal direction is still present. Therefore, in this embodiment, after “capturing” the tiny object, free manipulation of three dimensions may be realized. As shown in FIG. 8B, in the first movement, a projection of the tiny object in an X-Y plane does not change, and the height rises from a first height to a second height; and in the second movement, the tiny object moves from a first position to a second position having a different horizontal position and height, and the projection and height of the tiny object in the X-Y plane change. It will be understood by a person skilled in the art that there are other ways of changing the height of the tiny object. In fact, after “capturing” the tiny object in any manner of the present invention, a height of a focusing position of the electron beam probe or probe scanning region may be changed to change a vertical position of the tiny object.

FIG. 9 illustrates different influence factors on a Coulomb force according to an embodiment of the present invention. a represents an influence of different EVB dose rates on the Coulomb force. As shown in the drawing, as the electron beam dose rate increases, the Coulomb force gradually increases, which is very consistent with the theoretical calculation. b represents a relationship between an electron beam dose rate and the Coulomb force in the case of an annular electron beam instead of an EVB. As shown in the drawing, the annular electron beam instead of the EVB has a small influence on the experimental result. c represents an influence of a ratio of a probe size to a particle size on the Coulomb force. As shown in the drawing, as the probe, i.e., an annular region formed by the electron beam in a fluid medium, increases in size, the Coulomb force increases rapidly and reaches the extreme value when approximately 1.5 times, then gradually decreases and decreases to a very small amplitude after about 2 times and then remains substantially unchanged. Interestingly, if the tiny object to be moved is assumed to be square and the shape of the probe is circular, the Coulomb force reaches the extreme value when the tiny object is approximately the largest square appearing in the circular region. Therefore, it is indicated that the minimum probe size ensuring that the object to be moved does not enter the probe region corresponds to the extreme value of the Coulomb force. Therefore, the Coulomb force for manipulating the tiny object may be adjusted by adjusting the size and shape of the probe. d represents a relationship between an electron beam dose rate of a non-metallic silicon dioxide Si02 particle and the Coulomb force. As shown in the drawing, for a non-conductor tiny object, the solution of the present invention may also achieve precise manipulation, although the Coulomb force for manipulation is slightly smaller than that of a tiny object as a conductor.

In some embodiments, the magnitude of the gradient force is changed by changing the dose rate of the electron beam probe or probe scanning region. The higher the dose rate, the larger the Coulomb force. In some embodiments, the gradient force is changed by changing a position of the electron beam probe or probe scanning region relative to the tiny object. When the electron beam probe or probe scanning region is spaced from the tiny object, the closer the electron beam probe or probe scanning region, the larger the Coulomb force. In some embodiments, the gradient force is changed by changing the shape of the electron beam probe or probe scanning region. The higher the matching degree between the shape of the charged particle beam probe or probe scanning region and the shape of the tiny object, the larger the relative area, the larger the Coulomb force. In some embodiments, according to different manipulation operations, the dose rate of the electron beam probe or probe scanning region and the shape and position of the scanning region may be flexibly adjusted, so that a required force is obtained, and high-precision manipulation of a tiny object is realized.

In the foregoing embodiments, the horizontal position and height of the tiny object are adjusted by adjusting a horizontal position and a vertical position of the electron beam probe or probe scanning region. In some embodiments, the tiny object may also be rotated by using an electron beam.

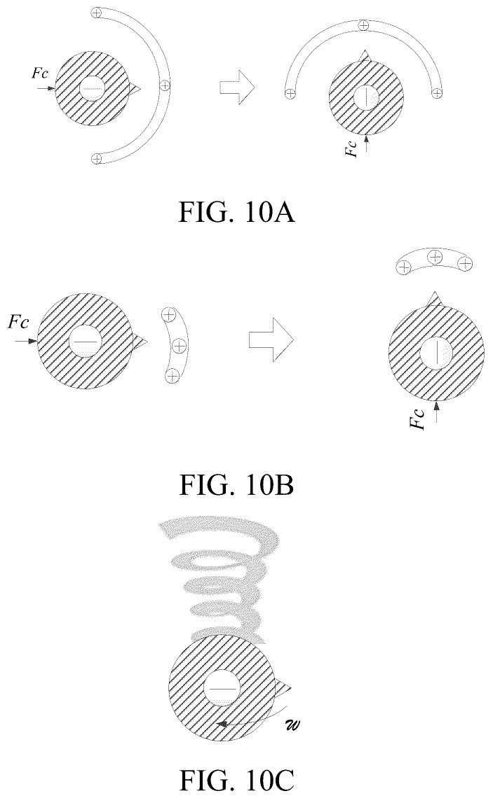

FIG. 10A is a schematic diagram of changing an angle of a tiny object according to an embodiment of the present invention. As shown in the drawing, in an initial position, a semi-annular electron beam probe or probe scanning region surrounds a tiny object, and the tip of the tiny object points to a first direction. By adjusting the electron beam probe or probe scanning region to move same from the first direction of the tiny object to a second direction perpendicular to the first direction, the tip of the tiny object also changes from pointing to the first direction to pointing to the second direction.

FIG. 10B is a schematic diagram of changing an angle of a tiny object according to another embodiment of the present invention. As shown in the drawing, in an initial position, an electron beam probe or probe scanning region is close to a tiny object in a first direction, and the tip of the tiny object points to the first direction. By adjusting the electron beam probe or probe scanning region to move same from the first direction of the tiny object to a second direction perpendicular to the first direction, the tip of the tiny object also changes from pointing to the first direction to pointing to the second direction.

FIG. 10C is a schematic diagram of rotating an angle of a tiny object according to an embodiment of the present invention. As shown in the drawing, an EVB acts directly on a tiny object, and the EVB interacts with the tiny object and transfers the carried angular momentum, so that the tiny object rotates.

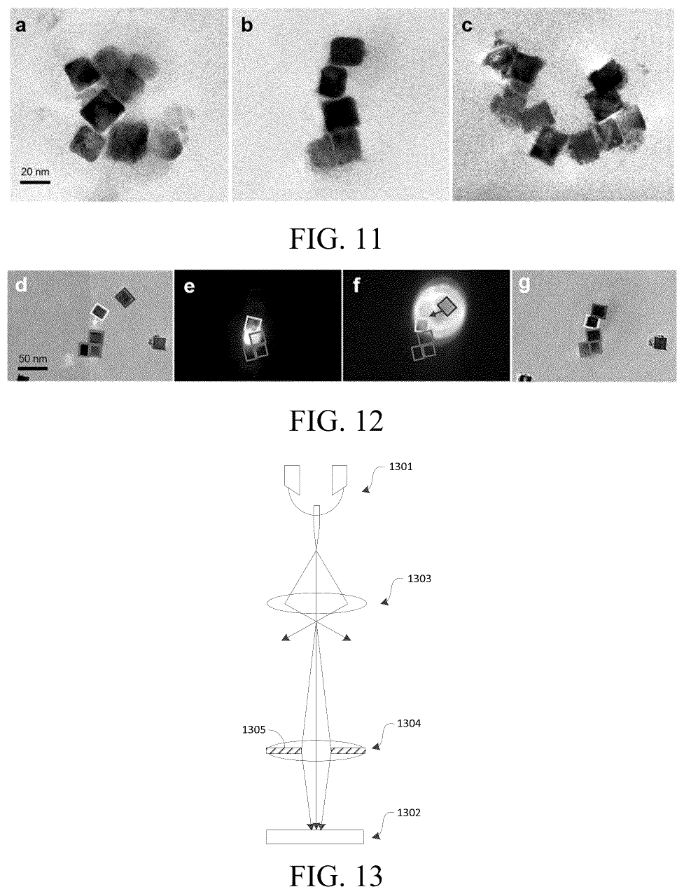

FIG. 11 is an example of nanoparticle manipulation and assembly according to an embodiment of the present invention. As shown in the drawing, a plurality of nanoscale metal Pd particles are captured by an EVB, and a pattern of an English abbreviation “ZJU” for “Zhejiang University” is formed by high-precision manipulation and assembly. FIG. 12 is an image of a manipulation and assembly process of some nanoparticles of the letter “J” in the embodiment shown in FIG. 11. As shown in the embodiments shown in FIG. 11 and FIG. 12, high-precision manipulation and assembly capabilities of the technical solutions of the present invention in the nanometer field are not asserted, but have been verified by experiments, and will become a basis for many possible applications of the present invention in the future.

FIG. 13 is a schematic structural diagram of a device for manipulating a tiny object according to an embodiment of the present invention. As shown in the drawing, the device for manipulating the tiny object includes: an electron gun 1301, configured to provide an electron beam; and a fluid medium chamber 1302, configured to accommodate a fluid medium and a tiny object. The electron beam forms a non-uniform charge distribution in a fluid medium within the fluid medium chamber, such that a gradient force is applied to the tiny object. As shown in the drawing, the device of this embodiment further includes one or more adjustment devices 1303-1305 configured to adjust the electron beam generated from the electron gun.

In some embodiments, the electron gun 1301 may be a thermal emission electron gun or a field emission electron gun. As will be appreciated by a person skilled in the art, other electron guns may also be applied to the present invention to provide electron beams.

In some embodiments, the fluid medium chamber 1302 may be a closed chamber, and the fluid medium and the tiny object are accommodated in the chamber. For example, the fluid medium chamber 1302 may include a liquid cell. In some embodiments, for a fluid medium with a very small volatility, a non-closed or open chamber may also be used to accommodate the fluid medium and the tiny object, for example, the fluid medium chamber 1302 may include a barrel body, and a fluid medium layer is carried on a bottom surface of the barrel body. As will be appreciated by a person skilled in the art, other types of closed or non-closed chambers capable of accommodating a fluid medium may also be applied in the present invention.

In some embodiments, the adjustment device includes an electromagnetic lens, such as first and second condenser lenses 1303 and 1304. Many attributes of the electron beam such as a focusing position, a beam spot size, an electron beam intensity, and monochromaticity may be adjusted by adjusting the electromagnetic lens. In some embodiments, the adjustment device includes a diaphragm, such as a diaphragm 1305 at the second condenser lens 1304. Electron beams of different configurations, focusing positions and orbital angular momentum may be obtained through different diaphragms. For example, the diaphragm 1305 may be one of a computer-generated hologram diaphragm, an annular diaphragm, and an arc-shaped diaphragm.

As will be appreciated by a person skilled in the art, there are various methods and devices for electron beam adjustment in the prior art. These methods and devices for electron beam adjustment may be applied to the present invention to obtain the required electron beam probe or probe scanning region. These are all within the scope of the present invention, and details are not described herein again.

In some embodiments, the adjustment device includes a vortex beam device configured to generate an electron vortex beam (EVB) carrying orbital angular momentum. As stated above, there are multiple methods for generating the EVB in the prior art. Only the computer-generated hologram diaphragm is exemplified below, and a spiral phase structure is formed by regulating a phase of the electron beam to obtain the EVB. However, the solutions of the present invention are not limited thereto.

According to the concept of a wave function of quantum mechanics, the most concise physical expression form of the EVB is derived by combining the concept of the de Broglie matter waves and the Schrodinger equation:
de Broglie matter waves:

$$λ = \frac{h}{p} = \frac{h}{\sqrt{2 mE}} ( h : Planck constant ; p : momentum ; λ : wavelength )$$

Schrodinger equation:

$$ih \frac{\partial }{\partial t} ϕ = H ϕ ( H : Hamiltonian operator )$$

EVB expression:

φₗ(r,φ,z)=e^{ik}^{_{z}}^{z}e^{ilφ}Jₗ(k⊥r)
where h is a Planck constant; p is a momentum; λ is a wavelength; r, φ, and z are three-dimensional coordinates of the EVB; l is an orbital angular momentum feature value (i.e., a topological charge); Jₗ is a first-order cylindrical Poisson equation; and k⊥ is a lateral momentum of the EVB.

According to the foregoing theory, the topological charge directly depends on the phase of the electrons. Therefore, the phase of the electron beam is regulated by the computer-generated hologram diaphragm to obtain EVBs having different topological charges (i.e., different orbital angular momentum).

In some embodiments of the present invention, a horizontal position, a vertical position, and/or an angle relative to the tiny object of the electron beam probe or probe scanning region may be adjusted by the adjustment device so as to move horizontally, move in a vertical direction, and rotate the tiny object, or implement a combination of said manipulations. In some embodiments, an angular momentum transfer of the electron beam to the tiny object may be adjusted by the adjustment device, so that the tiny object rotates.

In microscopic force interaction, the Coulomb force is a strong force. Moreover, since the Coulomb force is related to the number of charges, the Coulomb force has a wide adjustment range, which provides a basis for completing complex manipulation of a tiny object. Moreover, the solutions in some embodiments of the present invention are not limited to a nanoscale, and obviously, may also be applied to manipulation of a tiny object of a microscale or more. In combination with manipulation techniques for microscopic objects of other scales, a more practical and flexible microscopic operation could be possibly realized.

By means of the foregoing embodiments, it can be easily seen that the technical solutions of the present invention implement 4D high-precision manipulation of the tiny object, which is a non-contact manipulation, and does not easily cause damage to the manipulated tiny object. Further, the present invention extends manipulation to a nanoscale, and may be applied to various microscopic tiny objects such as conductors, non-conductors, and living or non-living biological cells or organelles, and therefore surely promote great progress in the fields of physics, chemistry, biology and medicine, thereby changing the whole historical process of the human science and technology.

The present invention further includes the technical solution for implementing more complex manipulation for a tiny object.

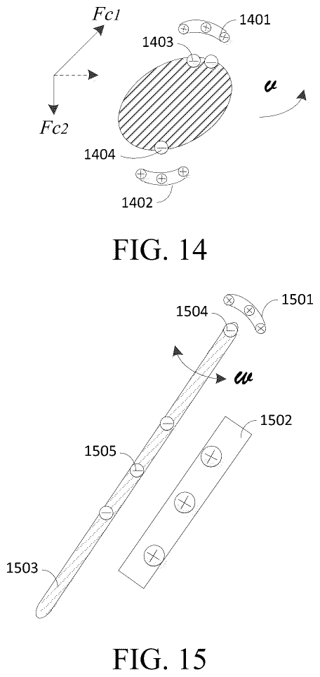

FIG. 14 is a schematic diagram of manipulating a tiny object according to another embodiment of the present invention. As shown in the drawing, a fluid medium includes a first electron beam probe or probe scanning region 1401 and a second electron beam probe or probe scanning region 1402. A non-uniform charge distribution formed by the first electron beam probe or probe scanning region 1401 applies a first gradient force FC1 to the tiny object; and a non-uniform charge distribution formed by the second electron beam probe or probe scanning region 1402 applies a second gradient force FC2 to the tiny object. Under a combined action of the first gradient force and the second gradient force, a motion state of the tiny object is converted from a stationary state to a constant motion at a speed of V (considering resistance).

In this embodiment, as shown in the drawing, the tiny object has a locally charged situation. A charge corresponding to the first electron beam probe or probe scanning region 1401 appears in a first portion 1403 of the tiny object; and a charge corresponding to the second electron beam probe or probe scanning region 1402 appears in a second portion 1404. Regardless of whether the tiny object is a conductor or a non-conductor, this locally charged situation may occur. This makes the manipulation of the present invention finer than the overall manipulation of the tiny object. Likewise, if the size of the tiny object is larger, the manipulation based on a plurality of electron beam probes or probe scanning regions is also more convenient, and the cost is lower. Therefore, such a manner imparts greater flexibility to tiny object manipulation.

FIG. 15 is a schematic diagram of manipulating a tiny object according to another embodiment of the present invention. As shown in the drawing, a fluid medium includes a first electron beam probe or probe scanning region 1501 and a second electron beam probe or probe scanning region 1502. A tiny object 1503 is substantially rod-shaped and extends in a length direction thereof. The first electron beam probe or probe scanning region 1501 is close to one end of the tiny object 1503; and the second electron beam probe or probe scanning region 1502 also extends in the length direction and is close to the rod body in a direction perpendicular to the length direction. A charge 1504 appears at the end of the tiny object 1503 close to the first electron beam probe or probe scanning region 1501, and a charge 1505 appears in the section of the rod body close to the second electron beam probe or probe scanning region 1502. When the first electron beam probe or probe scanning region 1501 remains stationary, the second electron beam probe or probe scanning region 1502 pushes the rod-shaped tiny object 1503 to rotate at an angular velocity of w with its end as an axis.

In some embodiments, the electron beam probe or probe scanning region is as close as possible to the tiny object to apply a greater gradient force, but remains spaced apart from the tiny object. In some embodiments, the electron beam probe or probe scanning region and the tiny object surface have corresponding shapes. For example, the tiny object surface is arc-shaped, and the electron beam probe or probe scanning region may also be arc-shaped. Likewise, at least one of the probes or probe scanning regions in the vertical direction may include a neck region that will apply a gradient force to a portion of the tiny object in the vertical direction, thereby controlling a height of the tiny object or a portion thereof.

The manner of controlling the gradient force may also be the same as that of the previous embodiments. In some embodiments, the gradient force may be changed by changing a dose rate of at least one of the charged particle beams; the gradient force is changed by changing a shape of at least one of the charged particle beam probes or probe scanning regions; or, the gradient force is changed by changing a position of the charged particle beam probe or probe scanning region relative to the tiny object. Certainly, a combination of the manners of changing the gradient force may also be employed to select an optimal manner to obtain a required gradient force for manipulation.

In some embodiments, the tiny object may be “captured” by a plurality of gradient forces, to maintain the tiny object in a relatively stationary state. In this state, if a horizontal position of the electron beam probe or probe scanning region is changed, a position of the tiny object or a portion thereof may be horizontally moved; if a vertical position of the probe or probe scanning region is changed, a height of the tiny object or a portion thereof may be adjusted; and if a relative position of the electron beam probe or probe scanning region, the tiny object is rotated.

The manipulation methods shown in the embodiments of FIGS. 14 and 15 may be implemented by the device of the embodiment shown in FIG. 13 if the electron beam probe scanning region applies a gradient force. However, in some cases, in order to implement more complex manipulation, a plurality of electron guns and a plurality of adjustment devices may be used for implementation.

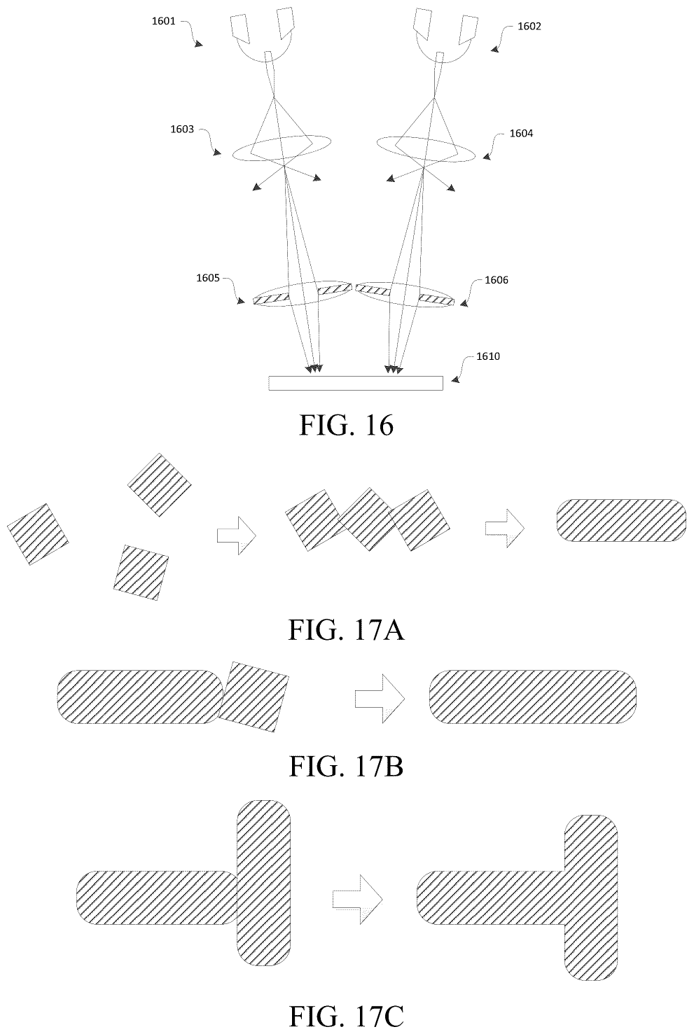

FIG. 16 is a schematic diagram of a device for manipulating a tiny object according to an embodiment of the present invention. As shown in the drawing, the device of this embodiment includes: a first electron gun 1601 and a second electron gun 1602, and a first set of condenser lenses 1603 and 1605 and a second set of condenser lenses 1604 and 1606 respectively corresponding to the first electron gun 1601 and the second electron gun 1602, where the condenser lenses 1605 and 1606 may accommodate a computer-generated hologram diaphragm. The first set of condenser lenses 1603 and 1605 and the second set of condenser lenses 1604 and 1606 respectively direct two different electron beams to a fluid medium chamber 1610 which accommodates a fluid medium and a tiny object to be manipulated. Two sets of adjustment devices represented by the first set of condenser lenses 1603 and 1605 and the second set of condenser lenses 1604 and 1606 may each independently adjust the electron beams from different electron guns 1601 and 1602 to realize independent control of different gradient forces, so that a motion state of the tiny object may be controlled more conveniently and flexibly.

As will be appreciated by a person skilled in the art, the embodiments of FIGS. 13 and 16 are merely illustrative embodiments of a device for manipulating a tiny object. Due to the fact that the manipulation technology of the electron beams is quite mature, various modifications and variations emerge one after another. These modifications and variations may be applied to the present invention to obtain a device for manipulating a tiny object that is more precise and flexible to manipulate.

The present invention not only includes capturing and moving a tiny object, but also includes a method and device for connecting tiny objects to manufacture a micro device.

As defined herein, “connection” refers to associating two objects into one piece. After connection, a change in a motion state of one object will likely affect the other object. In some embodiments, the two connected objects become a whole. In some embodiments, the two connected objects may still retain partial independence.

As defined herein, “contact” indicates that the distance between two objects is close enough, so that although there may still be a distance between the two objects, the yielded effect is approximately the same as the effect of the two objects colliding with each other. In other words, even if the two tiny objects are in contact, there may still be a smaller distance between the two tiny objects than their size.

Various methods may be employed to connect tiny objects including nanoscale tiny objects. In some embodiments, the two tiny objects may be directly connected together in an electron beam welding manner. An application range of the tiny object includes: metal and low-melting-point organic materials such as resin and plastic. For example, a first tiny object and a second tiny object in contact may be heated by using an electron beam, so that the first tiny object and the second tiny object are completely or partially melted. Since the electron beam heating controllability is very high, the electron beam heating may highly selectively weld the desired two tiny objects together.

In some embodiments, the two tiny objects may also be connected by using a laser heating method. However, due to the limitation of the wavelength of the laser, the laser will cause the metal tiny objects in a certain region to be completely or partially melted and welded together. For example, the first tiny object and the second tiny object in contact may be placed in a selected region, and the laser is adjusted to focus on the selected region, so that the first tiny object and the second tiny object in the region are welded together. In some embodiments, the laser heating method may connect a plurality of tiny objects in contact at a time, so as to improve efficiency.

For tiny objects which are not suitable for being connected in a welding manner, such as a tiny object including a high-melting-point material (such as Si02) or a material that is prone to high-temperature decomposition or direct volatilization, the connection may be performed in other manners. In some embodiments, a thermosetting material or an irradiation curing material may be coated on the surfaces of the tiny objects, and then these tiny objects are connected using an electron beam or a laser heating manner or an irradiation manner. Alternatively, an adhesive is included between the two tiny objects, and after the two tiny objects are in contact, these tiny objects are connected together by curing of the adhesive.

In some embodiments, a film layer including a phenolic resin and hexamethylenetetramine may be coated on the surfaces of the first tiny object and the second tiny object. After the first tiny object and/or the second tiny object are moved by an electron beam and are in contact each other, the first tiny object and the second tiny object in contact are directly heated by using the electron beam, and the film layers of the two tiny objects in contact are melted and further subjected to a thermosetting reaction, so that the first tiny object and the second tiny object are connected together. For another example, after the first tiny object and/or the second tiny object are moved to a certain selected region by an electron beam and are in contact with each other, then the laser is adjusted to focus on the selected region, so that the first tiny object and the second tiny object in the region are connected together through a thermosetting reaction between the film layers. As will be appreciated, the foregoing embodiments are merely illustrative embodiments of a tiny object surface that includes a thermosetting material. In some embodiments, the tiny object itself may be a thermosetting material. Alternatively, in some embodiments, other types of thermosetting resins or the like may also be applied to the solutions of the present invention.

In some embodiments, the surface of the tiny object is coated with a film layer including an irradiation curing material, such as a surface layer including a UV curing agent and starch. Likewise, the first tiny object and the second tiny object are moved to a selected region by an electron beam, and the selected region is irradiated with ultraviolet (UV) light, so that the first tiny object and the second tiny object in the region are connected together by means of an irradiation curing reaction. As will be appreciated, the foregoing embodiments are merely illustrative embodiments of a tiny object surface that includes an irradiation curing material layer. Other types of irradiation curing materials may also be applied to the solutions of the present invention.

In some embodiments, the fluid medium layer includes a plurality of adhesive particles. An electron beam is used to move the adhesive particles between the first and second tiny objects and to make contact with the two, the adhesive is heated directly using the electron beam to soften the adhesive so that the two tiny objects are brought into contact with each other by the adhesive; and the adhesive is then cured so that the first tiny object and the second tiny object are connected together. Likewise, adhesion of tiny objects may also be achieved by means of the adhesive in a laser heating manner. For certain types of adhesives, the manner of irradiation curing is also feasible.

In some embodiments, a portion of the tiny object may be a metal or low-melting-point material, while the other portion is other materials. The portion for connection with another tiny object is a metal or low-melting-point material portion, while the other portion is not affected.

The foregoing various connection manners may be used in combination according to actual requirements.

Further, as will be appreciated, a horizontal contact position between the first tiny object and the second tiny object may be defined by adjusting a horizontal position of one or more charged particle beam probes or probe scanning regions; a height contact position between the first tiny object and the second tiny object may be defined by adjusting a vertical position of the one or more charged particle beam probes or probe scanning regions; and further, a contact angle between the first tiny object and the second tiny object is defined by adjusting a relative position between the one or more charged particle beam probes or probe scanning regions and the first tiny object. Therefore, the first tiny object and the second tiny object may be connected to each other at any angle at any position. This provides a basis for the manufacturing of a complex micro device.

FIGS. 17A to 17C illustrate a schematic diagram of manufacturing a micro device according to an embodiment of the present invention. In FIG. 17A, a plurality of tiny objects are provided at a first time. The tiny objects are dispersed, and not in contact with each other. At a second time, one or more electron beams are used to move the plurality of tiny objects and make them be in contact with each other. In this case, the arrangement of the tiny objects is approximately the same as the desired micro device. At a third time, the tiny objects are connected in the foregoing described connection manners, so as to obtain the desired micro device, that is, a rod-shaped tiny object extending in the length direction. A connection between a rod-shaped tiny object and another tiny object and a connection between rod-shaped tiny objects are shown in FIGS. 17B and 17C, respectively. As will be appreciated, the rod-shaped tiny object may consist of smaller tiny objects as shown in FIG. 17A.

In some embodiments, as will be appreciated, the device for manipulating the tiny object of FIG. 13 or FIG. 16 may also be used to manufacture a micro device that include an electron gun configured to complete a connection between tiny objects in a fluid medium chamber.

In some embodiments, the device for manufacturing the micro device may further include a laser device configured to heat a region including a position where more than two tiny objects are located. In some embodiments, the device for manufacturing the micro device may further include an irradiation device configured to irradiate a region including a position where more than two tiny objects are located.

As will be appreciated, the foregoing embodiments are merely illustrative examples of manufacturing a micro device. Since the present invention extends manipulation of a tiny object to a nanoscale, the method of the present invention may be used to manufacture a micro device of a nanoscale or more; and further, due to the high accuracy and flexibility of the present invention, the manufacturing of a complex micro device may be realized by using the method of the present invention. These are great progress in the technical field.

Further, the present invention further includes a solution of automatically or at least partially automatically manufacturing a micro device.

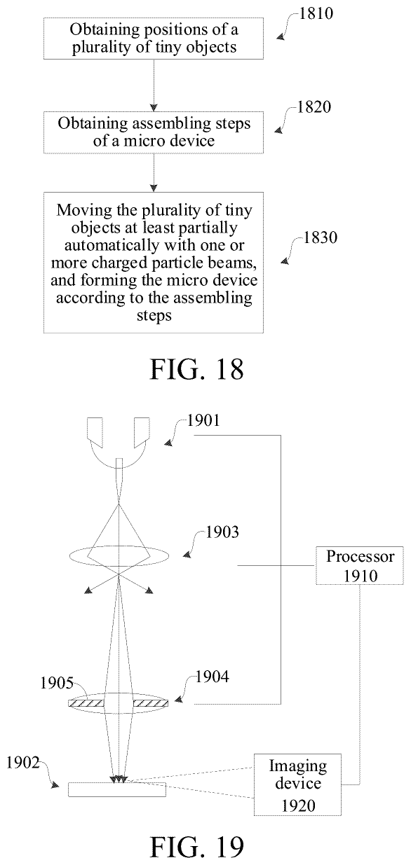

FIG. 18 illustrates a flowchart of a method for manufacturing a micro device according to an embodiment of the present invention. As shown in the drawing, the method includes the following steps: in step 1810, positions of a plurality of tiny objects are obtained. In some embodiments, an image of a micro device manufacturing region is obtained. The micro device manufacturing region may be all or a portion of the fluid medium chamber. By using the principle and devices of a transmission electron microscope (TEM) or a scanning electron microscope (SEM), the micro device manufacturing region may be conveniently imaged by transmitted electrons or secondary electrons formed by scanning, so as to obtain the image of the micro device manufacturing region.

In some embodiments, the method further includes: identifying types and positions of the plurality of tiny objects in the image of the micro device manufacturing region. By identifying and learning the types and positions of the tiny objects existing in the micro device manufacturing region, and establishing a resource library to facilitate the use of a subsequent algorithm, automatic manufacturing of the micro device is realized. The micro device manufacturing region may include a plurality of tiny objects with different sizes, materials and shapes, and these tiny objects may be in contact with each other or overlap each other. In some embodiments, different types of tiny objects are identified by a deep learning artificial intelligence algorithm.

For example, the types of the tiny objects are known, and an image set of a micro device manufacturing region including a plurality of tiny objects is taken as training data. The plurality of tiny objects included in the image set are manually labeled. An identification model is created through a CNN or other artificial intelligence neural networks with supervised learning, and identification results and positions of different types of tiny objects are outputted. Certainly, the foregoing is merely an example. A supervised or unsupervised algorithm based on other artificial intelligence neural networks may also be applied thereto, which is not limited in the present invention.

In some embodiments, after the types and positions of a plurality of tiny objects in the image of the micro device manufacturing region are identified, a resource library is established to classify and manage the identified tiny objects. For example, a resource table may be established to implement this purpose. Table 1 below is an example of such a resource table.

TABLE 1

| Resource type | Position 1 | Position 2 | Position 3 |
|---|---|---|---|
| Block 1 (with a diameter | (X11/Y11/Z11) | . . . | . . . |
| of 10-20 nm) | | | |
| Block 2 (with a diameter | (X21/Y21/Z21) | . . . | . . . |
| of 20-30 nm) | | | |
| Rod 1 (with a diameter of | (X11/Y11/Z11, | . . . | . . . |
| 1 and a length of 1) | A11/B11/C11) | | |
| Rod 2 (with a diameter of | (X21/Y21/Z21, | . . . | . . . |
| 1 and a length of 2) . . . | A21/B21/C21) | | |

Block 1 and block 2 respectively represent block-shaped tiny objects with different diameters. (X11/Y11/Z11) and (X21/Y21/Z21) respectively represent their position in the micro device manufacturing region (e.g., the positions where the centers are located). Rod 1 and rod 2 respectively represent rod-shaped tiny objects with the same diameter but different lengths. (X11/Y11/Z11, All/B11/C11) and (X21/Y21/Z21, A21/B21/C21) respectively represent their position in the micro device manufacturing region (e.g., the positions where the centers are located) and an extension direction (e.g., projection angles of the extension direction in three directions).

In step 1820, assembling steps of the micro device are obtained. In some embodiments, for a micro device that is desired to be manufactured, the manufacturing process thereof is decomposed into a plurality of assembling steps. These assembling steps include the step of forming an intermediate component on the basis of the types and/or quantity of the tiny objects, and the step of connecting the intermediate component with the tiny objects or another intermediate component.

In some embodiments, the assembling steps include: moving more than two tiny objects; moving connected more than two tiny objects; connecting more than two tiny objects in contact; connecting the connected more than two tiny objects with another tiny object; connecting more than two connected tiny objects; and simultaneously connecting two tiny objects in contact, more than two connected tiny objects or a combination thereof.

As will be appreciated, the same micro device may correspond to a plurality of different assembling steps. Obtaining these assembling steps related to the manufacturing of the micro device may provide a basis for subsequent automatic assembly.

In some embodiments, the assembling steps of the micro device are adjusted based at least in part on the types of the plurality of tiny objects. By comprehensively considering tiny object resources existing in the micro device manufacturing region displayed in the resource library and tiny object resources required for each assembling step, the assembling steps are adjusted, so that the assembly of the micro device may be completed more efficiently.

In some embodiments, the assembling steps of the micro device are adjusted based at least in part on the positions of the plurality of tiny objects. Different tiny object positions determine the energy and time required for moving these tiny objects. In order to manufacture the micro device more efficiently, the assembling steps of the micro device may also be adjusted according to the positions of the plurality of tiny objects. For example, if a few tiny objects are close to each other and are adapted to be processed into intermediate components required for a certain assembling step, then the assembling step may be adjusted to process the intermediate components nearby, and then subsequent assembly is performed.

Further, since the electron beam probe or probe scanning region thereof is limited in quantity, it is also necessary for reasonable planning to make full use of electron beam resources, thereby improving the manufacturing efficiency of the micro device.

In some embodiments, the manner of moving one or more of the plurality of tiny objects with one or more charged particle beams is determined based at least in part on the types of the plurality of tiny objects. As will be appreciated, a tiny object may be “captured” by using one electron beam probe or probe scanning region thereof, and a tiny object may also be “captured” by using a plurality of electron beam probes or probe scanning regions thereof. The manner of moving a plurality of tiny objects or intermediate components may be reasonably arranged according to the types of the plurality of tiny objects and the types of the intermediate components, and/or a movement distance.

In some embodiments, the order and route of using one or more charged particle beams to move one or more of the plurality of tiny objects are planned based at least on the positions of the plurality of tiny objects. As will be appreciated, the positions of the plurality of tiny objects are different, and the positions of the intermediate components may also be different. Therefore, moving which tiny objects or intermediate components, and the movement order and route could be reasonably arranged, thereby improving the manufacturing efficiency of the micro device.

In some embodiments, the order and route of using one or more charged particle beams to move one or more of the plurality of tiny objects are planned based at least in part on the assembling steps of the micro device. As will be appreciated, the sequence of the assembling steps also affects the movement of the tiny objects. Therefore, moving which tiny objects or intermediate components, and the movement order and route could be reasonably arranged according to the assembling steps, thereby improving the manufacturing efficiency of the micro device.

As will be appreciated, a person skilled in the art could comprehensively consider the foregoing factors or other factors, and combine the foregoing methods or other methods to obtain suitable optimized steps for the micro device.

In step 1830, the plurality of tiny objects are moved at least partially automatically with one or more charged particle beams and the micro device is formed according to the assembling steps. After the assembling steps are obtained, each assembling step may be decomposed into a plurality of actions, and then the plurality of actions are converted into control instructions for the electron beam probe or probe scanning region. These control instructions are capable of automatically or at least partially automatically controlling the electron beam adjustment device, performing each action of each assembling step, and completing each assembling step, thereby obtaining a desired micro device.

FIG. 19 is a schematic structural diagram of a device for manufacturing a micro device according to an embodiment of the present invention. As shown in the drawing, the device for manufacturing the micro device of this embodiment includes: an electron gun 1901, configured to provide an electron beam; a fluid medium chamber 1902, configured to accommodate a fluid medium and a plurality of tiny objects; one or more adjustment devices including condenser lenses 1903 and 1904 and a computer-generated hologram diaphragm 1905; a processor 1910; and an imaging device 1920, configured to obtain an image of a plurality of tiny objects in the fluid medium chamber. The processor 1902 is configured to: obtain positions of the plurality of tiny objects according to the image in the fluid medium chamber obtained by the imaging device; obtain assembling steps of a desired micro device according to the micro device; and control the one or more adjustment devices to at least partially automatically move the plurality of tiny objects with one or more charged particle beams and form the micro device according to the assembling steps. As will be appreciated, the processor 1910 may also be configured to perform the following functions: identifying the types and positions of the plurality of tiny objects in the image; and adjusting the assembling steps of the micro device.

In some embodiments, the device of this embodiment further includes a laser device. The processor 1910 is further configured to control the laser device to simultaneously connect more than two tiny objects in contact, more than two connected tiny objects in contact, or a combination of the two.

In some embodiments, the device of this embodiment further includes an irradiation device. The processor 1910 is further configured to control the irradiation device to simultaneously connect more than two tiny objects in contact, more than two connected tiny objects in contact, or a combination of the two.

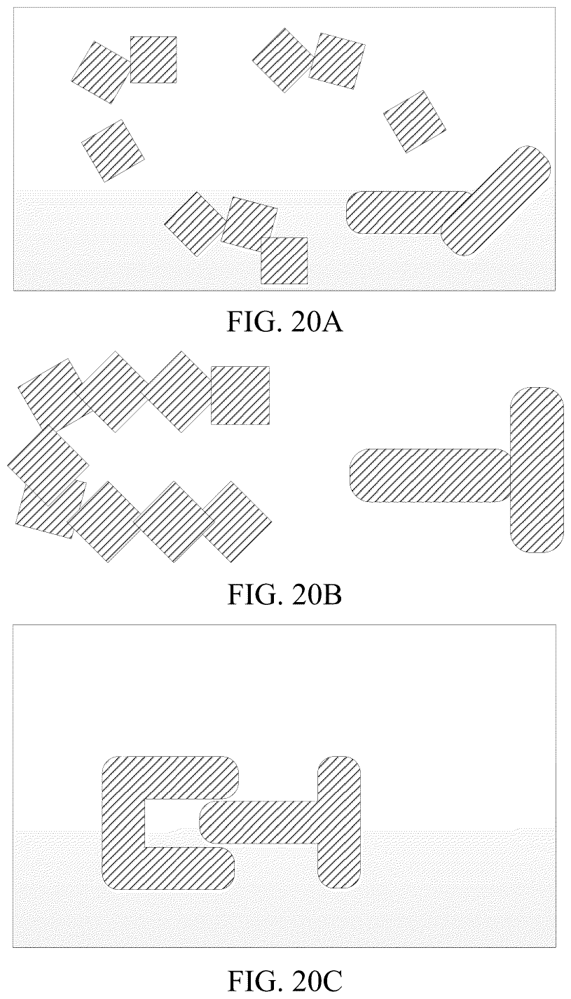

FIGS. 20A to 20C are schematic diagrams of a manufacturing process of a micro device according to an embodiment of the present invention. As shown in the drawing, the micro device desired to be manufactured is an insertion device which includes a socket and a plug. In FIG. 20A, a plurality of tiny objects are dispersed in the micro device manufacturing region, and include a plurality of block-shaped tiny objects and a plurality of rod-shaped tiny objects. After the image of the micro device manufacturing region is obtained and identified, a plurality of tiny object resources included in the micro device manufacturing region may be obtained.

Further, according to a result of the micro device that is desired to be manufactured, the assembling steps of the micro device are obtained: (1) using the dispersed block-shaped tiny objects to form a socket; (2) using the two rod-shaped tiny objects to form a plug; (3) simultaneously connecting the tiny objects forming the socket and plug; and (4) inserting the plug into the socket.

In FIG. 20B, the plurality of block-shaped tiny objects are moved and placed to form a generally socket shape, and the two rod-shaped tiny objects are moved to form a generally plug shape.

In FIG. 20C, the entire micro device manufacturing region is heated by laser, and the plurality of block-shaped tiny objects are connected to form a socket. An opening width of the socket is substantially equivalent to the diameter of the rod-shaped tiny object. The two rod-shaped tiny objects are connected to form a plug. Then, the plug is moved to be inserted into the socket. Thus, manufacturing of the desired micro device is achieved. As will be appreciated, all of the steps in this embodiment may be performed automatically.

The automatic or at least partially automatic assembly of the micro device of the present invention may greatly improve the manufacturing efficiency of the micro device, provides a condition for large-scale manufacturing of the micro device in a pipeline manner, and also provides a basis for the industrial application of the present invention.

The foregoing embodiments are merely intended to describe the present invention rather than limit the present invention. A person skilled in the art may also make modifications and variations without departing from the scope of the present invention. Therefore, all equivalent technical solutions shall also fall within the scope of the present invention.

1. A method for manipulating a tiny object, comprising:
providing a charged particle beam;
forming a non-uniform charge distribution in a fluid medium; and
applying, to a tiny object, a gradient force formed by the non-uniform charge distribution.

2. The method according to claim 1, wherein the gradient force is a Coulomb force.

3. The method according to claim 1, wherein the charged particle beam causes the tiny object to be charged.

4. The method according to claim 1, wherein the tiny object is at least partially a conductor.

5. The method according to claim 1, wherein the tiny object is at least partially a non-conductor.

6. The method according to claim 1, wherein the charged particle beam is an electron beam.

7. The method according to claim 1, wherein the charged particle beam is a vortex beam.

8. The method according to claim 1, wherein the non-uniform charge distribution is generated by the charged particle beam passing through a region of the fluid medium.

9. The method according to claim 8, wherein the non-uniform charge distribution is defined by a shape of a charged particle beam probe.

10. The method according to claim 1, wherein the non-uniform charge distribution is generated by the charged particle beam scanning a region of the fluid medium.

11. The method according to claim 10, wherein the non-uniform charge distribution is defined by a shape of a charged particle beam probe scanning region.

12. The method according to claim 1, wherein a charged particle beam probe or probe scanning region surrounds or at least partially surrounds the tiny object.

13. The method according to claim 12, wherein the shape of the probe or the probe scanning region in a plane of the tiny object is a ring, and the tiny object is located in the ring.

14. The method according to claim 12, wherein the shape of the probe or the probe scanning region in a plane of the tiny object is an arc, and the tiny object is located on one side of a circle center of the arc.

15. The method according to claim 12, wherein a ratio of a size of the probe or the probe scanning region to a size of the tiny object in a plane of the tiny object is about 1.5-1:1.

16. The method according to claim 12, wherein the tiny object does not exceed a range of the probe or the probe scanning region.

17. The method according to claim 12, wherein the shape of the charged particle beam probe or the probe scanning region in a vertical direction comprises a neck region configured to apply a gradient force in the vertical direction.

18. The method according to claim 1, wherein the gradient force is used for capturing the tiny object.

19. The method according to claim 1, further comprising: changing the gradient force by changing a dose rate of the charged particle beam.

20. The method according to claim 1, further comprising: changing the gradient force by changing the shape of a charged particle beam probe or probe scanning region.

21. The method according to claim 1, further comprising: changing the gradient force by changing a position of a charged particle beam probe or probe scanning region relative to the tiny object.

22. The method according to claim 1, further comprising: moving a position of the tiny object horizontally by adjusting a horizontal position of a charged particle beam probe or probe scanning region.

23. The method according to claim 1, further comprising: adjusting a height of the tiny object by adjusting a vertical position of a charged particle beam probe or probe scanning region.

24. The method according to claim 1, further comprising: rotating the tiny object by adjusting an angle of a charged particle beam probe or probe scanning region relative to the tiny object.

25. The method according to claim 1, further comprising: rotating the tiny object through an angular momentum transfer of a charged particle beam probe to the tiny object.

26. A device for manipulating a tiny object, comprising:
a charged particle gun, configured to provide a charged particle beam;
an adjustment device, configured to adjust the charged particle beam from the charged particle gun; and
a fluid medium chamber, configured to accommodate a fluid medium and a tiny object;
wherein the charged particle beam is adjusted to form a non-uniform charge distribution in the fluid medium within the fluid medium chamber, such that a gradient force is applied to the tiny object.

27. The device according to claim 27, wherein the charged particle gun comprises an electron gun.

28. The device according to claim 27, wherein the fluid medium chamber comprises a liquid cell.

29. The device according to claim 27, wherein the adjustment device comprises one or more electromagnetic lenses.

30. The device according to claim 27, wherein the adjustment device comprises one or more diaphragms.

31. The device according to claim 27, wherein the adjustment device comprises a vortex beam device configured to generate a charged particle beam carrying orbital angular momentum.

32. The device according to claim 31, wherein the vortex beam device comprises one or more of a computer-generated hologram diaphragm, an annular diaphragm, and an arc-shaped diaphragm.

33. The device according to claim 27, wherein the adjustment device is configured to move the tiny object horizontally by adjusting a horizontal position of a charged particle beam probe or probe scanning region.

34. The device according to claim 27, wherein the adjustment device is configured to adjust a height of the tiny object by adjusting a vertical position of a charged particle beam probe or probe scanning region.

35. The device according to claim 27, wherein the adjustment device is configured to rotate the tiny object by adjusting an angle of a charged particle beam probe or probe scanning region relative to the tiny object.

36. The device according to claim 27, wherein the adjustment device is configured to rotate the tiny object by adjusting an angular momentum transfer of a charged particle beam probe to the tiny object.
